(19) United States
(12) Patent Application Publication
(10) Pub. No.: US 2026/0311961 A1
(43) Pub. Date: Oct. 8, 2026

(54) COMPENSATING FOR COLLECTION VARIATION OF SCANNING CHARGED PARTICLE-OPTICAL APPARATUS

(71) Applicant: ASML Netherlands B.V., Veldhoven (NL)

(72) Inventors: Robert Maikel GOOSEN, Eindhoven (NL); Jasper Frans Mathijs VAN RENS, Hegelsom (NL)

(73) Assignee: ASML Netherlands B.V., Veldhoven (NL)

(21) Appl. No.: 19/482,293

(22) PCT Filed: Apr. 8, 2024
(86) PCT No.: PCT/EP2024/059497

§ 371 Date: Nov. 7, 2025

(30) Foreign Application Priority Data
May 8, 2023 (EP) 23172032.7

(51) Int. Cl. H01J 37/26; H01J 37/153; H01J 37/28

(52) U.S. Cl. CPC H01J 37/265; H01J 37/153; H01J 37/28; H01J 2237/0048; H01J 2237/1534; H01J 2237/24495; H01J 2237/2806

(57) ABSTRACT

A charged particle-optical apparatus for scanning a sample with charged particles and detecting signal charged particles emitted from the sample, the charged particle-optical apparatus comprising: a charged particle-optical device configured to direct a charged particle beam onto a field of view of the sample; a detector comprising a plurality of detector elements configured to detect signal charged particles emitted from respective locations within the field of view, so as to generate scan data; and a controller configured to compensate for variation across the field of view of a proportion of signal charged particles emitted from the locations that are incident on the respective detector elements, such that an effect of the variation on the scan data is reduced.

### CROSS-REFERENCE TO RELATED APPLICATIONS

This application claims priority of EP application 23172032.7 which was filed on 8 May 2023 and which is incorporated herein in its entirety by reference.

### TECHNICAL FIELD

The embodiments provided herein disclose a charged particle-optical apparatus, a method of operating a charged particle-optical apparatus, a method for correcting scan data, a method for determining at least one compensation parameter value and a non-transitory computer readable medium.

### BACKGROUND

In manufacturing processes of integrated circuits (ICs), unfinished or finished circuit components are assessed to ensure that they are manufactured according to design and are free of defects. Assessment (e.g. metrology or inspection) systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in assessment (e.g. metrology or defect detection and inspection) become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as critical dimension, periodicity and placement error metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput assessment of two-dimensional and three-dimensional structures.

### SUMMARY

An embodiment of the present disclosure provides a charged particle-optical apparatus for scanning a sample with charged particles and detecting signal charged particles emitted from the sample, the charged particle-optical apparatus comprising: a charged particle-optical device configured to direct a charged particle beam onto a field of view of the sample; a detector comprising a plurality of detector elements configured to detect signal charged particles emitted from respective locations within the field of view, so as to generate scan data; and a controller configured to compensate for variation across the field of view of a proportion of signal charged particles emitted from the locations that are incident on the respective detector elements, such that an effect of the variation on the scan data is reduced.

An embodiment of the present disclosure provides a method of operating a charged particle-optical apparatus for scanning a sample with charged particles and detecting signal charged particles emitted from the sample, the method comprising: a charged particle-optical device of the charged particle-optical apparatus directing a charged particle beam onto a field of view of the sample; a plurality of detector elements of a detector of the charged particle-optical apparatus detecting signal charged particles emitted from respective locations within the field of view, so as to generate scan data; and compensating for variation across the field of view of a proportion of signal charged particles emitted from the locations that are incident on the respective detector elements, such that an effect of the variation on the scan data is reduced.

An embodiment of the present disclosure provides a method of processing scan data, the method comprising: providing scan data, wherein the scan data has been generated by a charged particle-optical apparatus scanning a field of view of a sample with charged particles and detecting signal charged particles emitted from locations within the field of view with a plurality of respective detector elements of a detector of the charged particle-optical apparatus; and correcting the scan data so as to compensate for variation across the field of view of a proportion of signal charged particles emitted from the locations that are incident on the respective detector elements, such that an effect of the variation on the scan data is reduced.

An embodiment of the present disclosure provides a method of determining at least one compensation parameter value for a charged particle-optical apparatus for scanning a sample with charged particles and detecting signal charged particles emitted from the sample, the method comprising: a charged particle-optical device of the charged particle-optical apparatus directing a charged particle beam onto at least one field of view of the sample, wherein the field of view is substantially featureless; a plurality of detector elements of a detector of the charged particle-optical apparatus detecting signal charged particles emitted from respective locations within the at least one field of view, so as to generate measurement data; recording the measurement data associated with the locations as a record of variation across the field of view of a proportion of signal charged particles emitted from the locations that are incident on the respective detector elements; and determining at least one compensation parameter value to be applied by a controller of the charged particle-optical apparatus so as to compensate for the variation in a subsequent scan on a sample comprising features.

An embodiment of the present disclosure provides a non-transitory computer readable medium that stores instructions for a processor of a controller to carry out a method of operating a charged particle-optical apparatus the method comprising: controlling a charged particle-optical device of the charged particle-optical apparatus to direct a charged particle beam onto a field of view of a sample; controlling a plurality of detector elements of a detector of the charged particle-optical apparatus to detect signal charged particles emitted from respective locations within the field of view, so as to generate scan data; and compensating for variation across the field of view of a proportion of signal charged particles emitted from the locations that are incident on the respective detector elements, such that an effect of the variation on the scan data is reduced.

An embodiment of the present disclosure provides a non-transitory computer readable medium that stores instructions for a processor of a controller to carry out a method of processing scan data, the method comprising: providing scan data, wherein the scan data has been generated by a charged particle-optical apparatus scanning a field of view of a sample with charged particles and detecting signal charged particles emitted from locations within the field of view with a plurality of respective detector elements of a detector of the charged particle-optical apparatus; and correcting the scan data so as to compensate for variation across the field of view of a proportion of signal charged particles emitted from the locations that are incident on the respective detector elements, such that an effect of the variation on the scan data is reduced.

An embodiment of the present disclosure provides a non-transitory computer readable medium that stores instructions for a processor of a controller to carry out a method of determining at least one compensation parameter value for a charged particle-optical apparatus, the method comprising: controlling a charged particle-optical device of the charged particle-optical apparatus to direct a charged particle beam onto at least one field of view of the sample, wherein the field of view is substantially featureless; controlling a plurality of detector elements of a detector of the charged particle-optical apparatus to detect signal charged particles emitted from respective locations within the at least one field of view, so as to generate measurement data; recording the measurement data associated with the locations as a record of variation across the field of view of a proportion of signal charged particles emitted from the locations that are incident on the respective detector elements; and determining at least one compensation parameter value to be applied by a controller of the charged particle-optical apparatus so as to compensate for the variation in a subsequent scan on a sample comprising features.

An embodiment of the present disclosure provides a scanning electron microscope, SEM, for scanning a sample with electrons and detecting signal electrons emitted from the sample, the SEM comprising: an electron-optical device configured to direct an electron beam onto a field of view of the sample; a detector comprising a plurality of detector elements configured to detect signal electrons emitted from respective locations within the field of view, so as to generate SEM scan data; and a controller configured to compensate for variation across the field of view of a proportion of signal electrons emitted from the locations that are incident on the respective detector elements, such that an effect of the variation on the SEM scan data is reduced.

An embodiment of the present disclosure provides a method of operating a scanning electron microscope, SEM, for scanning a sample with electrons and detecting signal electrons emitted from the sample, the method comprising: an electron-optical device of the SEM directing an electron beam onto a field of view of the sample; a plurality of detector elements of a detector of the SEM detecting signal electrons emitted from respective locations within the field of view, so as to generate SEM scan data; and compensating for variation across the field of view of a proportion of signal electrons emitted from the locations that are incident on the respective detector elements, such that an effect of the variation on the SEM scan data is reduced.

An embodiment of the present disclosure provides a method of determining at least one compensation parameter value for a scanning electron microscope, SEM, for scanning a sample with electrons and detecting signal electrons emitted from the sample, the method comprising: an electron-optical device of the SEM directing an electron beam onto at least one field of view of the sample, wherein the field of view is substantially featureless; a plurality of detector elements of a detector of the SEM detecting signal electrons emitted from respective locations within the at least one field of view, so as to generate SEM measurement data; recording the SEM measurement data associated with the locations as a record of variation across the field of view of a proportion of signal electrons emitted from the locations that are incident on the respective detector elements; and determining at least one compensation parameter value to be applied by a controller of the SEM so as to compensate for the variation in a subsequent scan on a sample comprising features.

An embodiment of the present disclosure provides a non-transitory computer readable medium that stores instructions for a processor of a controller to carry out a method of operating a scanning electron microscope, SEM, the method comprising: controlling an electron-optical device of the SEM to direct an electron beam onto a field of view of a sample; controlling a plurality of detector elements of a detector of the SEM to detect signal electrons emitted from respective locations within the field of view, so as to generate SEM scan data; and compensating for variation across the field of view of a proportion of signal electrons emitted from the locations that are incident on the respective detector elements, such that an effect of the variation on the SEM scan data is reduced.

An embodiment of the present disclosure provides a non-transitory computer readable medium that stores instructions for a processor of a controller to carry out a method of determining at least one compensation parameter value for a scanning electron microscope, SEM, the method comprising: controlling an electron-optical device of the SEM to direct an electron beam onto at least one field of view of the sample, wherein the field of view is substantially featureless; controlling a plurality of detector elements of a detector of the SEM to detect signal electrons emitted from respective locations within the at least one field of view, so as to generate SEM measurement data; recording the SEM measurement data associated with the locations as a record of variation across the field of view of a proportion of signal electrons emitted from the locations that are incident on the respective detector elements; and determining at least one compensation parameter value to be applied by a controller of the SEM so as to compensate for the variation in a subsequent scan on a sample comprising features.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings in which:

FIG. 1 is a schematic diagram illustrating an exemplary electron beam assessment system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam assessment system of FIG. 1.

FIG. 3 is a view of a portion of the electron detection device of FIG. 2A, the detector of FIG. 2B or the electron detection device of FIG. 2C.

FIG. 4 is a view of a modified version of a portion of the electron detection device of FIG. 2A, the detector of FIG. 2B or the electron detection device of FIG. 2C.

FIG. 5 is a diagram of fields of view of different sizes.

FIG. 6 is a graph showing the relationship between position within the field of view and collection efficiency.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied.

One component of improving yield is monitoring the chip making process to ensure that it is producing a sufficient number of functional integrated circuits. One way to monitor the process is to assess the chip circuit structures at various stages of their formation. Assessment can be carried out using an SEM. An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. It may be desirable to have higher throughput for defect detection and assessment processes to meet the requirements of IC manufacturers.

In order to image the small structures, the electron beam deposits electrons within a small area, after which the electrons which are emitted are counted. Next the beam of electrons is displaced and the process is repeated until the whole field of view if interest has been scanned. The electron counts correspond to how dark or light the parts of the image corresponding to those locations are. Some electrons will miss the detector and so will not be counted. One challenge is that the proportion of electrons emitted from the sample that are detected (i.e. counted) varies depending on the location within the field of view. This variation in collection efficiency can be compensated for either before or after the electrons are counted. Before the electrons are counted, the detector elements in locations with higher collection efficiency can be partially turned off so that their effective collection efficiency is more uniform to other locations. After the electrons are counted, the electron counts for locations with higher collection efficiency can be reduced (and/or the electron counts for locations with lower collection efficiency can be increased) so that the results are what you would expect if the collection efficiency were more uniform.

The idea is to correct the collection efficiency fingerprint of the SEM, for each choice of SEM settings. The collection efficiency fingerprint for a given set of SEM settings, shows the variations in collection efficiency as a function of SEM image coordinates. The correction can be done by:
keeping the SEM settings constant and do the correction offline in the post-processing of images.
locally adjusting SEM settings (dose) as function of SEM image coordinates, so during acquisition of a single SEM image.

The collection efficiency fingerprint in a SEM image will depend on the choice of SEM settings. The fingerprint can be measured for all possible choices of SEM settings. Interpolating the fingerprints from SEM setting to SEM setting is possible to reduce the number of required calibrations.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

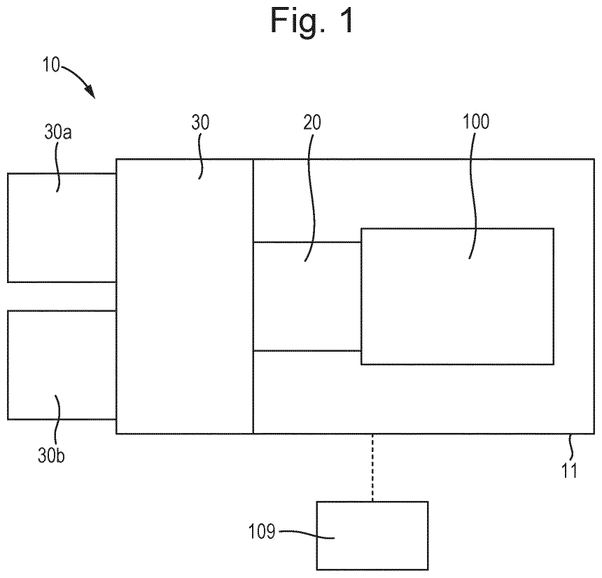

Reference is now made to FIG. 1, which illustrates an exemplary electron beam assessment system 10 that may include a detector, consistent with embodiments of the present disclosure. assessment system 10 may be used for imaging. As shown in FIG. 1, the assessment system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be assessed (wafers and samples may be collectively referred to as “samples” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to assessment by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of the assessment system 10. While controller 109 is shown in FIG. 1 as being outside of the structure that includes main chamber 11, load/lock chamber 20, and EFEM 30, it is appreciated that controller 109 can be part of the structure.

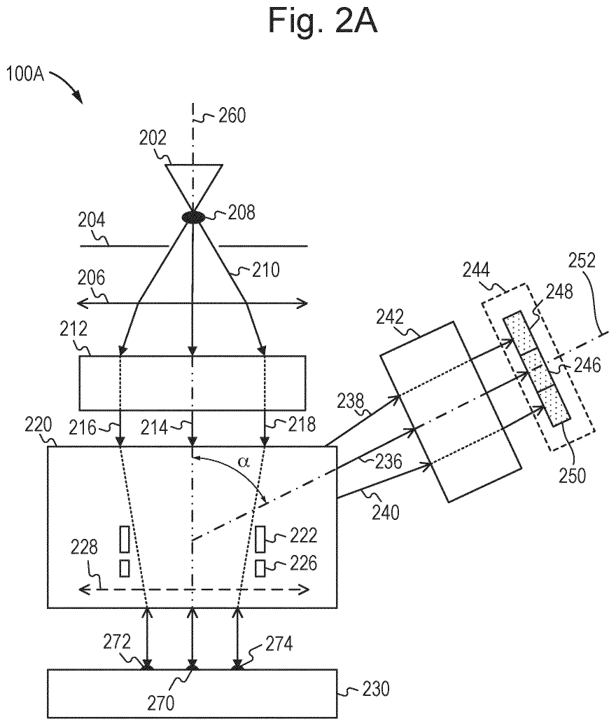

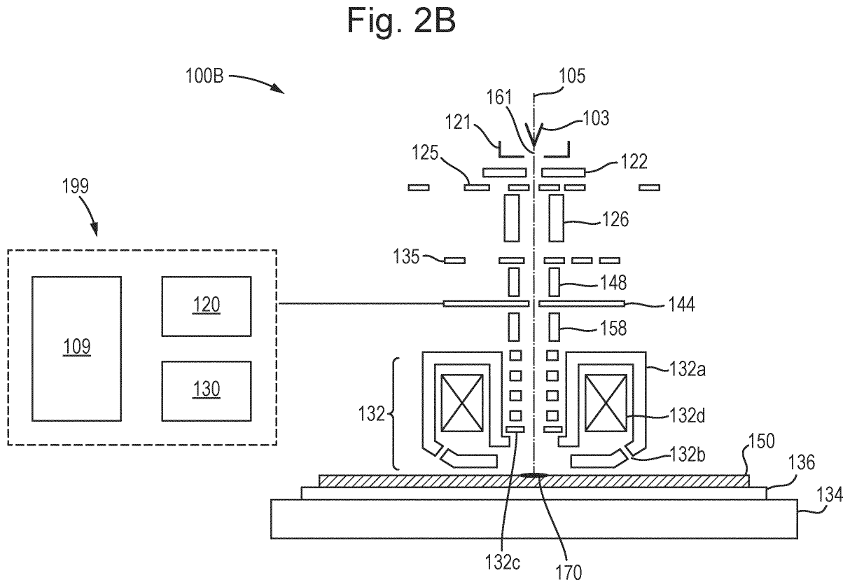

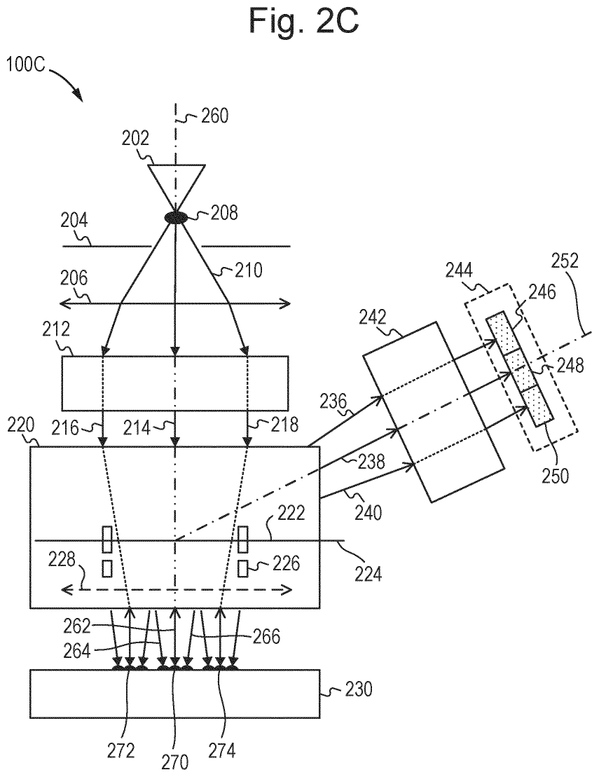

FIG. 2A illustrates a charged particle beam apparatus in which an assessment system may comprise a multi-beam assessment tool that uses multiple primary electron beamlets to simultaneously scan multiple locations on a sample.

As shown in FIG. 2A, an electron beam tool 100A (also referred to herein as an electron beam apparatus 100A or an electron-optical device) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of electron beam apparatus 100A. Secondary optical system 242 and electron detection device 244 may be aligned with a secondary optical axis 252 of electron beam apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. A moveable condenser lens is further described in U.S. Publication No. 2017/0025241, which is incorporated by reference in its entirety.

Objective lens 228 may focus beamlets 214, 216, and 218 onto a wafer 230 (i.e. a sample) for assessment and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as electron beam apparatus 100B) may be a single-beam assessment tool that is used in the assessment system 10. Electron beam apparatus 100B includes an electron-optical device configured to project electrons towards a sample location (i.e. where the wafer is) and a wafer holder 136 supported by motorized stage 134 to hold a wafer 150 (i.e. a sample) to be assessed. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, Internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an assessment system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. However, some embodiments may use a detector placed off-axis relative to the optical axis along which the primary electron beam travels. For example, as in the embodiment shown in FIG. 2A, beam separator 222 may be provided to direct secondary electron beams toward a detector placed off-axis. Beam separator 222 may be configured to divert secondary electron beams by an angle α.

Another example of a charged particle beam apparatus will now be discussed with reference to FIG. 2C. Electron beam tool 100C (also referred to herein as an electron beam apparatus 100C or an electron-optical device) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread ΔV into beamlet portions 262 corresponding to energy V0, beamlet portion 264 corresponding to energy V0+ΔV/2, and beamlet portion 266 corresponding to energy V0−ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector (sometimes called a “PIN detector”) may be used in apparatus 100 in the assessment system 10. The assessment system 10 may be a high-speed wafer imaging SEM including an image processor. An electron beam generated by the assessment system 10 may irradiate the surface of a sample or may penetrate the sample. The assessment system 10 may be used to image a sample surface or structures under the surface, such as for analyzing layer alignment. In some embodiments, the assessment system 10 may detect and report process defects relating to manufacturing semiconductor wafers by, for example, comparing SEM images against device layout patterns, or SEM images of identical patterns at other locations on the wafer under assessment. A PIN detector may include a silicon PIN diode that may operate with negative bias. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

In an embodiment the detector (e.g. the electron detection device 244 shown in FIG. 2A or FIG. 2C or the detector 144 shown in FIG. 2B) comprises a plurality of detector elements (e.g. detection sub-regions 246, 248, and 250). The detector elements may be connected to one or more circuit layers. A circuit layer of the detector may comprise circuitry having amplification and/or digitation functions, e.g. it may comprise a amplification circuit. A circuit layer may comprise one or more trans impedance amplifiers (TIAs) and one or more ADCs. A detector element and an associated feedback resistor may be connected to the TIA and ADC. One or more digital signal lines may be connected from the ADC for transferring digital signals, e.g. to the image acquirer 120 shown in FIG. 2B.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting a sensing element, or performing image processing. In an embodiment the controller is configured to control settings of the ADCs. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

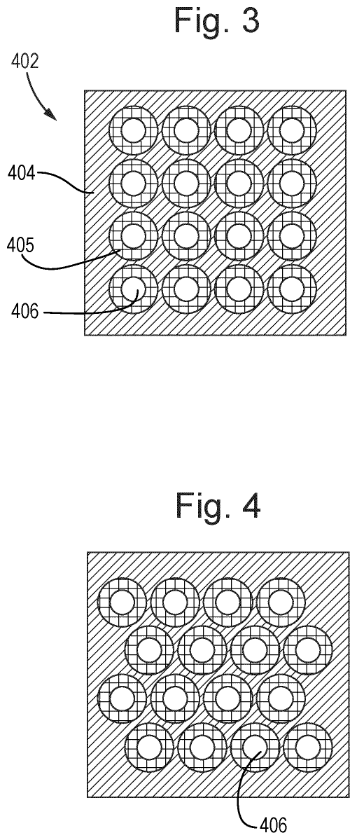

An exemplary embodiment of a portion of a detector 144 or electron detection device 244 is shown in FIG. 3. The view is of a surface onto which electrons are incident and detected. In this embodiment, the detector 144 or electron detection device 244 comprises a detector module 402 comprising a plurality (e.g., an array) of detector elements 405. The detector elements 405 may be sensor elements such as capture electrodes. In an embodiment there is an array of detector elements 405 (i.e. a plurality of detector elements 405 in a pattern or arrangement preferably over a two dimensional surface). In an embodiment the detector module 402 comprises a substrate 404 on which are provided a plurality of detector elements 405 (e.g. capture electrodes) each surrounding a beam aperture 406. The beam apertures 406 may be formed by etching through the substrate 404. In the arrangement shown in FIG. 3, the beam apertures 406 are shown in a rectangular array. The beam apertures 406 can also be differently arranged, e.g. in a hexagonal close packed array as depicted in FIG. 4.

An electron beam apparatus 100, such as is shown in FIG. 2A, FIG. 2B or FIG. 2C may scan a sample with one or more electron beams. The electron beam apparatus 100 is configured to detect signal electrons emitted from the sample so as to generate scan data. The scan data may be image data. An image may be generated from the scan data. The scan data may be data of currents of signal electrons emitted from different locations of the sample. The electron beam apparatus 100 may be embodied as an SEM. The scan data may be SEM image data.

In an embodiment the SEM forms an image by creating a pixelated excitation map. The electron beam illuminates a small part of the sample. The small part may be referred to as the field of view. The number of electrons emitted by the sample represents the signal of interest. The number of admitted electrons per illuminated position within the field of view is the signal which forms the image of the field of view. In an embodiment the detector 144 or electron detection device 244 is configured to measure the signal. The detector 144 or the electron detection device 244 may be generally referred to below as the detector.

As shown in FIG. 3 and FIG. 4, the detector comprises a plurality of detector elements 405. The detector elements 405 may be referred to as detector areas. As shown in FIG. 3 and FIG. 4, the detector elements 405 do not form a continuous uninterrupted surface. Instead, there are spaces between detector elements 405 and spaces (i.e. beam apertures 406) inside the detector elements 405. In particular, as shown in FIG. 3 and FIG. 4, in an embodiment the detector elements are shaped like an annulus. Some electrons may pass through the beam apertures 406, while other electrons may miss the outer edge of the detector elements 405. This results in a collection efficiency which is less than 100%.

In an embodiment the electron beam apparatus 100 comprises a detector 144, 244 comprising a plurality of detector elements 405 configured to detect signal electrons emitted from respective locations within the field of view, so as to generate scan data. The signals detected by the detector elements 405 from the pixelated excitation map. In an embodiment each detector element 405 detects the signal corresponding to a pixel of the pixelated excitation map.

In an embodiment the electron beam apparatus 100 comprises a controller 109. The controller is configured to compensate for variation across the field of view of a proportion of signal electrons emitted from the locations that are incident on the respective detector elements 405. The proportion of signal electrons emitted from the locations that are incident on the respective detector elements 405 is the collection efficiency. By compensating for the variation in collection efficiency, an effect of the variation on the scan data is reduced.

By reducing the effect of the variation of collection efficiency on the scan data, the accuracy of the scan data may be increased. An embodiment of the disclosure is expected to improve measurement of the sample. An embodiment of the disclosure is expected to reduce errors in measurements of the sample. For example, an embodiment of the disclosure is expected to reduce errors in the determined critical dimension (CD), which may be determined from the SEM scan data.

In an embodiment the controller 109 is configured to compensate for the variation dependent on a value of at least one scan parameter of the scanning of the sample as input.

As mentioned above, the collection efficiency may vary across the field of view of the sample. For example, the extent to which the location within the field of view is off axis may affect the collection efficiency. In an embodiment the centre of the field of view is on axis, i.e. in line with the electron-optical axis of the electron beam apparatus 100. Other locations within the field of view are off axis to a greater or lesser extent. The angle at which the signal electrons are emitted from the sample may affect the likelihood that the emitted signal electrons are incident on the detector elements 405. For example, a small angle relative to the electron-optical axis may result in emitted signal electrons passing through the beam aperture 406 that is surrounded by the detector element 405. A greater angle may result in emitted signal electrons missing the outside edge of the detector elements 405. In general, it is expected that more emitted signal electrons pass through the beam aperture 405 than miss the outside edge of the detector element 405.

However, it is not only the location within the field of view that affects the collection efficiency. The collection efficiency may also depend on one or more scan parameters. A scan parameter is a parameter of the electron beam apparatus 100 and/or the electron beam during scanning of a sample. Scan parameters that are considered to be particularly important in having an effect on the collection efficiency are described below.

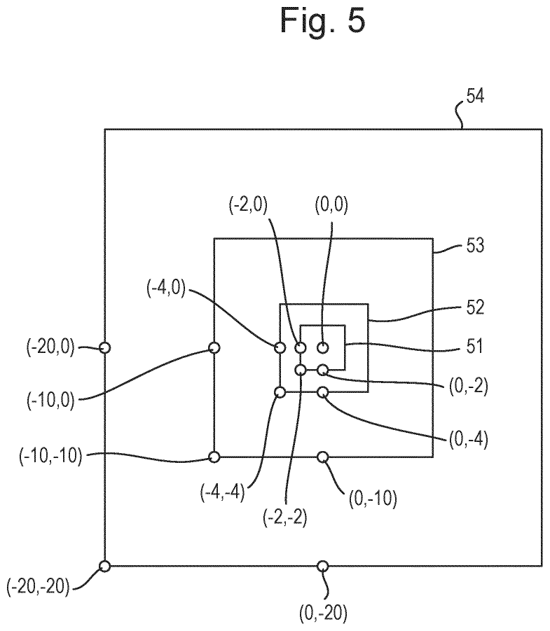

FIG. 5 is a diagram of fields of view 51 to 54 of different sizes. In the arrangement shown in FIG. 5, each field of view 51 to 54 has a square shape. However, it is not essential for the field of view to have a square shape. In an alternative embodiment, the field of view may have a rectangular shape, a hexagonal shape, a triangular shape, an elliptical shape or a circular shape, for example. The field of view used may have different sizes. In FIG. 5, the first field of view 51 is a square of size 4 units. The units may be, for example, μm. Alternatively, the units may be 0.1 μm, 0.2 μm, 0.5 μm, 2 μm, 5 μm or 10 μm, for example. The second field of view 52 is a square shape of size 8 units. The third field of view 53 is a square shape of size 20 units. The fourth field of view 54 is a square shape of size 40 units.

FIG. 5 shows coordinates for the centre (0,0) of the fields of view 51 to 54. In an embodiment, the centre (0,0) is on axis. The centre is aligned with the electron-optical axis of the electron beam apparatus 100. FIG. 5 shows, for each field of view, three further coordinates which are off axis. The coordinates of the locations are shown in FIG. 5 using the units. For example, the point (−2,0) is off axis by 2 μm, when the units are um.

In an embodiment a scan of a featureless sample is performed so as to obtain scan data for each of the locations shown in FIG. 5. This measured data provides information about how the collection efficiency varies for different locations within the field of view 51 to 54. If the collection efficiency were uniform across the field of view, then the detected signals would be expected to be uniform for a featureless substrate. A featureless substrate is a substrate that does not have structures on it. The featureless substrate is a substantially flat surface. The featureless substrate has a uniform surface. The featureless substrate is configured to emit the same number of signal electrons for each location for a given current of incident electron beam.

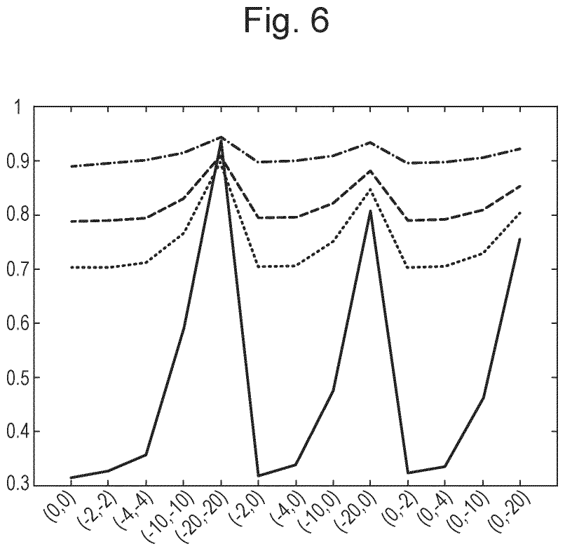

FIG. 6 is a graph showing the relationship between the location relative to the axis and the collection efficiency. The X axis shows the emission position. The positions indicated in FIG. 6 correspond to the locations shown in FIG. 5. The Y axis shows the collection efficiency. A collection efficiency of 1 would mean that all of the signal electrons are incident on the detector elements 405.

As shown in FIG. 6, the collection efficiency is not uniform across the fields of view 51-54. Instead, there is variation.

FIG. 6 shows four different graph lines. Each line corresponds to a different value of a scan parameter. The scan parameter is the electric potential applied to the electron-optical element of the electron-optical device closest to the sample. The electric potential applied to this final element affects the acceleration of signal electrons emitted from the sample. The element may be referred to as an extraction element. The extraction element affects extraction of signal electrons from the substrate. The electric potential applied to the extraction element may also affect the focus of the electron beam on the sample. The electric potential applied to the extraction element is a scan parameter considered to have a significant effect on the collection efficiency. As shown in FIG. 6, the four different graph lines show different collection efficiencies. This shows the effect of the electric potential applied to the final electron-optical element (i.e. the extraction element).

In FIG. 6, the top graph line with the highest collection efficiency corresponds to the lowest electric potential applied to the extraction element. The next graph line with the next highest collection efficiency in general has the next lowest electric potential applied to the extraction element. The next graph line with the next highest collection efficiency in general has the next lowest electric potential applied to the extraction element. The bottom graph line with the lowest collection efficiency in general corresponds to the highest electric potential applied to the extraction element.

As shown in FIG. 6, in general the collection efficiency appears to peak for locations that are furthest from the axis. This may be because at these locations the proportion of emitted signal electrons that pass through the beam aperture 406 is generally reduced.

As shown in FIG. 6, the collection efficiency can vary a large amount across the field of view. By compensating for the variation in collection efficiency, an embodiment of the disclosure is expected to improve the quality of the scan data and measurements that can be made from the scan data.

By taking into account a value of at least one scan parameter, the controller 109 may compensate for the variation in collection efficiency more thoroughly. In an embodiment the at least one scan parameter comprises the electric potential applied to the extraction element. As indicated by FIG. 6, by taking into account the electric potential applied to the extraction element, the scan data may be better representative of the structures of the sample. The scan data may be more accurate.

In an embodiment the controller 109 is configured to control the electron-optical device so as to control a target energy of an electron when the electron is incident on the sample. The target energy may be referred to as the landing energy, i.e. the energy of electrons at the point that they land on the sample. In an embodiment the controller 109 is configured to control the target energy by controlling electric potentials applied to electron-optical elements within the electron-optical device. Electrons may be accelerated so as to increase their landing energy.

In an embodiment the at least one scan parameter comprises the target energy. That is, in an embodiment the controller is configured to compensate for the variation in collection efficiency dependent on the target energy as input. The target energy is considered to be a parameter that has a particularly significant effect on the collection efficiency. By taking into account the target energy (i.e. the landing energy) the scan data may be made more accurate. Measurements taken from the scan data may be less prone to error.

In an embodiment the controller 109 is configured to compensate for the variation in collection efficiency based on a model using the at least one scan parameter as input. The model may be a mathematical model. How the collection efficiency varies within the scan field of view can be predicted using a forward model. In an embodiment the model is configured to output an estimated collection efficiency for given inputs. The inputs may be the location within the field of view, and optionally one or more of the target energy (i.e. landing energy) and the electric potential applied to the extraction element. Alternatively, the model may not calculate the collection efficiency. Instead, the model may output compensation parameter values for the controller 109 to apply in a subsequent scan of a sample. In other words, the model may calculate how the compensation is to be achieved without necessarily calculating the collection efficiency.

In an embodiment, the controller 109 is configured to compensate for the variation in collection efficiency based on a look-up table. In an embodiment the look-up table associates values of the least one scan parameter the other values of a respective at least one compensation parameter of the compensation for the variation. For example, the look-up table may provide information of how the controller is to control a subsequent scan and generation of scan data for a given target energy and electric potential of the extraction element. How the collection efficiency varies within the scan field of view can be measured/collaborated in an experiment where the field of view contains a featureless area.

In an embodiment there is a method of determining at least one compensation parameter value for an electron beam apparatus 100. In an embodiment the method comprises the electron-optical device directing an electron beam onto at least one field of view of the sample. In an embodiment the field of view is substantially featureless.

In an embodiment a plurality of detector elements 405 of a detector 144, 244 of the electron beam apparatus 100 directs signal electrons emitted from the respective locations within the at least one field of view, so as to generate measurement data. Preferably, a plurality of fields of view are measured. For example, different sizes of fields of view may be measured as shown in FIG. 5, for example. The measurements made for the smaller fields of view may contribute to the measured data for the larger fields of view.

In an embodiment the method comprises recording the measurement data associated with the locations as a record of variation across the field of view of a proportion of signal electrons emitted from the locations that are incident on the respective detector elements 405. For example, the measurement data may be recorded as shown in FIG. 6 or otherwise.

In an embodiment the method comprises determining at least one compensation parameter value to be applied by the controller 109 so as to compensate for the variation in a subsequent scan on a sample that comprises features.

In an embodiment the scans to generate measurement data are repeated for different scan parameter values (e.g. different target landing energies and/or different electron centrals applied to the extraction element). This helps to build up an overall view of how the collection efficiency varies depending on the scan parameters as well as the location within the field of view. The measurement data may be recorded so as to determine compensation parameter values for different types of scan and different locations within the field of view.

In an embodiment the method comprises interpolating and/or extrapolating from the recorded compensation parameter values for the different scan parameter values. This helps to generate compensation parameter values for different, i.e. additional, scan parameter values. In other words, a model can be built up of how the controller 109 can compensate for the variation in collection efficiency for any given scan parameter values, even if experiments have not been performed for those specific scan parameter values.

In an embodiment, experiments may be performed for the scan parameter values that are expected to be most commonly used. In addition, extrapolation and/or interpolation techniques can be used to generate an overall model or look-up table for determining how the variation in collection efficiency may be compensated for, for any given scan parameter values.

In an embodiment the controller 109 is configured to compensate for the variation by correcting the scan data. The acquired collection efficiency map can be used to update the measured image. In an embodiment, the scan of the sample is performed in a standard way. However, the scan data that is generated is subsequently corrected so as to compensate for the variation in collection efficiency.

In an embodiment the controller 109 is configured to normalise the scan data relative to the proportion of emitted signal particles that reach the detector elements 405 (i.e. the collection efficiency). Different strategies can be applied to perform such an update. For example, the signals (e.g. counts of electrons) in locations that have a low collection efficiency may be upscaled. Additionally or alternatively, the high collection efficiency parts may be downscaled. It is also possible to work somewhere in the middle, e.g. by upscaling low efficiency parts as well as downscaling high collection efficiency parts. In an embodiment the signals (e.g. electron counts) are divided by the collection efficiency for that location so as to normalise the signals for the varying collection efficiency.

It is not essential to perform the scan in order to generate the scan data. In an alternative embodiment, there is a method of processing scan data. The method comprises providing scan data that has previously been generated by a scan. The scan data may be stored in a memory.

In an embodiment the method comprises correcting the scan data so as to compensate for the variation in collection efficiency. This reduces the effect of the variation on the scan data. For example, the scan data may be upscaled and/or downscaled as described above so as to normalise relative to the variation in collection efficiency. When correcting previously obtained scan data, it is not necessary to perform the scan because the scan data has already been obtained.

It is not essential to post-process the scan data in order to compensate for the variation in collection efficiency. In an alternative embodiment, the compensation is performed actively by adjusting the way that the scan data is generated. In an embodiment the controller 109 is configured to compensate for the variation by controlling an area of the detector elements 405 that contributes to the scan data when an electron is incident on it. In an embodiment the detector elements 405 each comprise a plurality of pixels (i.e. independently distinguishable areas).

In an embodiment the controller 109 is configured to selectively use the pixels so as to compensate for the variation. For example, in an embodiment the controller 109 is configured to switch off some of the pixels so that they do not count electrons. For example, for a detector element 405 corresponding to a location with a high collection efficiency, some of the pixels may be turned off so as to effectively reduce the collection efficiency at that location. In an embodiment the controller 109 is configured to control the detector elements 405 so as to effectively equalise (or at least reduce differences in) the collection efficiency across the detector 144, 244.

In an embodiment the pixels that are switched off are selected depending on the expected likelihood of emitted signal electrons being incident on them.

A further possibility is that the current of the electron beam incident on the sample may be adjusted depending on the location within the field of view. For example, in an embodiment the controller 109 is configured to compensate for the variation by controlling a current of the electron beam incident on the different locations within the field of view. For example, for locations that have a high collection efficiency, the controller 109 may control the electron-optical device so as to apply a relatively lower electron beam current. For locations with a lower collection efficiency, the current of the electron beam incident on it may be controlled to be higher.

In an embodiment the electron-optical device comprises an aberration corrector. The aberration corrector may be upbeam of the detector 144, 244. In an embodiment the aberration corrector is configured to reduce aberration of the electron beam. For example, the aberration corrector may be configured to reduce aberration so as to allow a smaller spot size incident on the sample.

By compensating for the variation in collection efficiency as described above, it may not be necessary to mitigate for the variation in collection efficiency by applying a Wien filter. A Wien filter may otherwise be used to deflect desirably electrons emitted from the sample so as to increase the collection efficiency. However, such a Wien filter can prevent an aberration corrector from functioning correctly. By not requiring a Wien filter, such an aberration corrector may be used. An embodiment of the disclosure is expected to compensate for collection efficiency variation while allowing a smaller spot size incident on the sample.

Another way of mitigating the variation in collection efficiency is to increase the distance between the detector and the sample. By compensating as described above, it may be possible to have the detector closer to the sample, without causing undue problems of collection efficiency variation. This is because the variation is compensated for.

In an embodiment a non-transitory computer readable medium stores instructions for a processor of a controller (e.g. the controller 109) to carry out a method as described above.

Exemplary embodiments of the present disclosure are set out in the following numbered clauses:
1. A charged particle-optical apparatus for scanning a sample with charged particles and detecting signal charged particles emitted from the sample, the charged particle-optical apparatus comprising:
   a charged particle-optical device configured to direct a charged particle beam onto a field of view of the sample;
   a detector comprising a plurality of detector elements configured to detect signal charged particles emitted from respective locations within the field of view, so as to generate scan data; and
   a controller configured to compensate for variation across the field of view of a proportion of signal charged particles emitted from the locations that are incident on the respective detector elements, such that an effect of the variation on the scan data is reduced.
2. The charged particle-optical apparatus of clause 1, wherein the controller is configured to compensate for the variation dependent on a value of at least one scan parameter of the scanning of the sample as input.
3. The charged particle-optical apparatus of clause 2, wherein the controller is configured to control the charged particle-optical device so as to control a target energy of a charged particle of the charged particle beam when the charged particle is incident on the sample.
4. The charged particle-optical apparatus of clause 3, wherein the at least one scan parameter comprises the target energy.
5. The charged particle-optical apparatus of any of clauses 2-4, wherein the charged particle-optical device comprises an extraction element arranged to face the sample, and the controller is configured to control an electric potential applied to the extraction element so as to control an acceleration of signal particles emitted from the sample.
6. The charged particle-optical apparatus of clause 5, wherein the at least one scan parameter comprises the electric potential applied to the extraction element.
7. The charged particle-optical apparatus of any of clauses 2-6, wherein the controller is configured to compensate for the variation based on a model using the at least one scan parameter as input.
8. The charged particle-optical apparatus of any of clauses 2-6, wherein the controller is configured to compensate for the variation based on a look-up table associating values of the at least one scan parameter with values of a respective at least one compensation parameter of the compensation for the variation.
9. The charged particle-optical apparatus of any preceding clause, wherein the controller is configured to compensate for the variation by correcting the scan data.
10. The charged particle-optical apparatus of clause 9, wherein the controller is configured to normalise the scan data relative to the proportion.
11. The charged particle-optical apparatus of any preceding clause, wherein the controller is configured to compensate for the variation by controlling an area of the detector elements that contributes to the scan data when a charged particle is incident on it.
12. The charged particle-optical apparatus of clause 11, wherein the detector elements comprise a plurality of pixels and the controller is configured to selectively use the pixels so as to compensate for the variation.
13. The charged particle-optical apparatus of any preceding clause, wherein the charged particle-optical device comprises an aberration corrector configured to reduce aberration of the charged particle beam.
14. A method of operating a charged particle-optical apparatus for scanning a sample with charged particles and detecting signal charged particles emitted from the sample, the method comprising:
   a charged particle-optical device of the charged particle-optical apparatus directing a charged particle beam onto a field of view of the sample;
   a plurality of detector elements of a detector of the charged particle-optical apparatus detecting signal charged particles emitted from respective locations within the field of view, so as to generate scan data; and
   compensating for variation across the field of view of a proportion of signal charged particles emitted from the locations that are incident on the respective detector elements, such that an effect of the variation on the scan data is reduced.
15. A method of processing scan data, the method comprising:
   providing scan data, wherein the scan data has been generated by a charged particle-optical apparatus scanning a field of view of a sample with charged particles and detecting signal charged particles emitted from locations within the field of view with a plurality of respective detector elements of a detector of the charged particle-optical apparatus; and
   correcting the scan data so as to compensate for variation across the field of view of a proportion of signal charged particles emitted from the locations that are incident on the respective detector elements, such that an effect of the variation on the scan data is reduced.
16. A method of determining at least one compensation parameter value for a charged particle-optical apparatus for scanning a sample with charged particles and detecting signal charged particles emitted from the sample, the method comprising:
   a charged particle-optical device of the charged particle-optical apparatus directing a charged particle beam onto at least one field of view of the sample, wherein the field of view is substantially featureless;
   a plurality of detector elements of a detector of the charged particle-optical apparatus detecting signal charged particles emitted from respective locations within the at least one field of view, so as to generate measurement data;
   recording the measurement data associated with the locations as a record of variation across the field of view of a proportion of signal charged particles emitted from the locations that are incident on the respective detector elements; and
   determining at least one compensation parameter value to be applied by a controller of the charged particle-optical apparatus so as to compensate for the variation in a subsequent scan on a sample comprising features.
17. The method of clause 16, wherein the directing and detecting steps are repeated for different values of at least one scan parameter so as to generate the measurement data and record the at least one compensation parameter for the different values of the at least one scan parameter.
18. The method of clause 17, comprising interpolating and/or extrapolating from the recorded at least one compensation parameter value for the different values of the at least one scan parameter, so as to generate compensation parameter values for additional values of the at least one scan parameter.
19. A non-transitory computer readable medium that stores instructions for a processor of a controller to carry out a method of operating a charged particle-optical apparatus the method comprising:
   controlling a charged particle-optical device of the charged particle-optical apparatus to direct a charged particle beam onto a field of view of a sample;
   controlling a plurality of detector elements of a detector of the charged particle-optical apparatus to detect signal charged particles emitted from respective locations within the field of view, so as to generate scan data; and
   compensating for variation across the field of view of a proportion of signal charged particles emitted from the locations that are incident on the respective detector elements, such that an effect of the variation on the scan data is reduced.
20. A non-transitory computer readable medium that stores instructions for a processor of a controller to carry out a method of processing scan data, the method comprising:
   providing scan data, wherein the scan data has been generated by a charged particle-optical apparatus scanning a field of view of a sample with charged particles and detecting signal charged particles emitted from locations within the field of view with a plurality of respective detector elements of a detector of the charged particle-optical apparatus; and
   correcting the scan data so as to compensate for variation across the field of view of a proportion of signal charged particles emitted from the locations that are incident on the respective detector elements, such that an effect of the variation on the scan data is reduced.
21. A non-transitory computer readable medium that stores instructions for a processor of a controller to carry out a method of determining at least one compensation parameter value for a charged particle-optical apparatus, the method comprising:
   controlling a charged particle-optical device of the charged particle-optical apparatus to direct a charged particle beam onto at least one field of view of the sample, wherein the field of view is substantially featureless;
   controlling a plurality of detector elements of a detector of the charged particle-optical apparatus to detect signal charged particles emitted from respective locations within the at least one field of view, so as to generate measurement data;
   recording the measurement data associated with the locations as a record of variation across the field of view of a proportion of signal charged particles emitted from the locations that are incident on the respective detector elements; and
   determining at least one compensation parameter value to be applied by a controller of the charged particle-optical apparatus so as to compensate for the variation in a subsequent scan on a sample comprising features.
22. A scanning electron microscope, SEM, for scanning a sample with electrons and detecting signal electrons emitted from the sample, the SEM comprising:
   an electron-optical device configured to direct an electron beam onto a field of view of the sample;
   a detector comprising a plurality of detector elements configured to detect signal electrons emitted from respective locations within the field of view, so as to generate SEM scan data; and
   a controller configured to compensate for variation across the field of view of a proportion of signal electrons emitted from the locations that are incident on the respective detector elements, such that an effect of the variation on the SEM scan data is reduced.
23. A method of operating a scanning electron microscope, SEM, for scanning a sample with electrons and detecting signal electrons emitted from the sample, the method comprising:
   an electron-optical device of the SEM directing an electron beam onto a field of view of the sample;
   a plurality of detector elements of a detector of the SEM detecting signal electrons emitted from respective locations within the field of view, so as to generate SEM scan data; and
   compensating for variation across the field of view of a proportion of signal electrons emitted from the locations that are incident on the respective detector elements, such that an effect of the variation on the SEM scan data is reduced.
24. A method of determining at least one compensation parameter value for a scanning electron microscope, SEM, for scanning a sample with electrons and detecting signal electrons emitted from the sample, the method comprising:
   an electron-optical device of the SEM directing an electron beam onto at least one field of view of the sample, wherein the field of view is substantially featureless;
   a plurality of detector elements of a detector of the SEM detecting signal electrons emitted from respective locations within the at least one field of view, so as to generate SEM measurement data;
   recording the SEM measurement data associated with the locations as a record of variation across the field of view of a proportion of signal electrons emitted from the locations that are incident on the respective detector elements; and
   determining at least one compensation parameter value to be applied by a controller of the SEM so as to compensate for the variation in a subsequent scan on a sample comprising features.
25. A non-transitory computer readable medium that stores instructions for a processor of a controller to carry out a method of operating a scanning electron microscope, SEM, the method comprising:
   controlling an electron-optical device of the SEM to direct an electron beam onto a field of view of a sample;
   controlling a plurality of detector elements of a detector of the SEM to detect signal electrons emitted from respective locations within the field of view, so as to generate SEM scan data; and
   compensating for variation across the field of view of a proportion of signal electrons emitted from the locations that are incident on the respective detector elements, such that an effect of the variation on the SEM scan data is reduced.
26. A non-transitory computer readable medium that stores instructions for a processor of a controller to carry out a method of determining at least one compensation parameter value for a scanning electron microscope, SEM, the method comprising:
   controlling an electron-optical device of the SEM to direct an electron beam onto at least one field of view of the sample, wherein the field of view is substantially featureless;
   controlling a plurality of detector elements of a detector of the SEM to detect signal electrons emitted from respective locations within the at least one field of view, so as to generate SEM measurement data;
   recording the SEM measurement data associated with the locations as a record of variation across the field of view of a proportion of signal electrons emitted from the locations that are incident on the respective detector elements; and
   determining at least one compensation parameter value to be applied by a controller of the SEM so as to compensate for the variation in a subsequent scan on a sample comprising features.

A non-transitory computer readable medium may be provided that stores instructions for a processor of a controller (e.g., the controller 109 of FIG. 1) to carry out image assessment (e.g. metrology or inspection), image acquisition, activating charged-particle source, adjusting electrical excitation of stigmators, adjusting landing energy of electrons, adjusting objective lens excitation, adjusting secondary electron detector position and orientation, stage motion control, beam separator excitation, applying scan deflection voltages to beam deflectors, receiving and processing data associated with signal information from electron detectors, configuring an electrostatic element, detecting signal electrons, adjusting the control electrode potential, adjusting the voltages applied to the electron source, extractor electrode, and the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged particle-optical apparatus for scanning a sample with charged particles and detecting signal charged particles emitted from the sample, the charged particle-optical apparatus comprising:
a charged particle-optical device configured to direct a charged particle beam onto a field of view of the sample;
a detector comprising a plurality of detector elements configured to detect signal charged particles emitted from respective locations within the field of view, so as to generate scan data; and
a controller configured to compensate for variation across the field of view of a proportion of signal charged particles emitted from the locations that are incident on the respective detector elements, such that an effect of the variation on the scan data is reduced.

2. The charged particle-optical apparatus of claim 1, wherein the controller is configured to compensate for the variation dependent on a value of at least one scan parameter of the scanning of the sample as input.

3. The charged particle-optical apparatus of claim 2, wherein the controller is configured to control the charged particle-optical device so as to control a target energy of a charged particle of the charged particle beam when the charged particle is incident on the sample.

4. The charged particle-optical apparatus of claim 3, wherein the at least one scan parameter comprises the target energy.

5. The charged particle-optical apparatus of claim 2, wherein the charged particle-optical device comprises an extraction element arranged to face the sample, and the controller is configured to control an electric potential applied to the extraction element so as to control an acceleration of signal particles emitted from the sample.

6. The charged particle-optical apparatus of claim 5, wherein the at least one scan parameter comprises the electric potential applied to the extraction element.

7. The charged particle-optical apparatus of claim 2, wherein the controller is configured to compensate for the variation based on a model using the at least one scan parameter as input.

8. The charged particle-optical apparatus of claim 2, wherein the controller is configured to compensate for the variation based on a look-up table associating values of the at least one scan parameter with values of a respective at least one compensation parameter of the compensation for the variation.

9. The charged particle-optical apparatus of claim 1, wherein the controller is configured to compensate for the variation by correcting the scan data.

10. The charged particle-optical apparatus of claim 9, wherein the controller is configured to normalise the scan data relative to the proportion.

11. The charged particle-optical apparatus of claim 1, wherein the controller is configured to compensate for the variation by controlling an area of the detector elements that contributes to the scan data when a charged particle is incident on it.

12. The charged particle-optical apparatus of claim 11, wherein the detector elements comprise a plurality of pixels and the controller is configured to selectively use the pixels so as to compensate for the variation.

13. The charged particle-optical apparatus of claim 1, wherein the charged particle-optical device comprises an aberration corrector configured to reduce aberration of the charged particle beam.

14. A method of operating a charged particle-optical apparatus for scanning a sample with charged particles and detecting signal charged particles emitted from the sample, the method comprising:
directing a charged particle beam onto a field of view of the sample using a charged particle-optical device of the charged particle-optical apparatus;
detecting, using a plurality of detector elements of a detector of the charged particle-optical apparatus, signal charged particles emitted from respective locations within the field of view, so as to generate scan data; and
compensating for variation across the field of view of a proportion of signal charged particles emitted from the locations that are incident on the respective detector elements, such that an effect of the variation on the scan data is reduced.

15. A method of processing scan data, the method comprising:
providing scan data, wherein the scan data has been generated by a charged particle-optical apparatus scanning a field of view of a sample with charged particles and detecting signal charged particles emitted from locations within the field of view with a plurality of respective detector elements of a detector of the charged particle-optical apparatus; and
correcting the scan data so as to compensate for variation across the field of view of a proportion of signal charged particles emitted from the locations that are incident on the respective detector elements, such that an effect of the variation on the scan data is reduced.
